(19) United States
(12) Patent Application Publication
(10) Pub. No.: US 2004/0144643 A1
(43) Pub. Date: Jul. 29, 2004

(54) Sputtering targets, sputter reactors, methods of forming cast ingots, and methods of forming metallic articles

(76) Inventors: Chi tse Wu, Veradale, WA (US); Wuwen Yi, Veradale, WA (US); Frederick B. Hidden, Spokane, WA (US); Susan D. Strothers, Spokane, WA (US)

Correspondence Address: WELLS ST. JOHN P.S., 601 W. FIRST AVENUE, SUITE 1300, SPOKANE, WA, 99201, US

(21) Appl. No.: 10/759,444

(22) Filed: Jan. 14, 2004

Related U.S. Application Data
(63) Continuation-in-part of application No. PCT/US01/45650, filed on Oct. 9, 2001.
(60) Provisional application No. 60/306,836, filed on Jul. 19, 2001.

(51) Int. Cl. C23C 14/32; C22F 1/08

(52) U.S. Cl. 204/298.12; 204/192.12; 204/298.13; 148/538; 148/553; 148/554; 148/559

(57) ABSTRACT

The invention encompasses a method of forming a metallic article. An ingot of metallic material is provided, and such ingot has an initial thickness. The ingot is subjected to hot forging. The product of the hot forging is quenched to fix an average grain size of less than 250 microns within the metallic material. The quenched material can be formed into a three dimensional physical vapor deposition target. The invention also includes a method of forming a cast ingot. In particular aspects, the cast ingot is a high-purity copper material. The invention also includes physical vapor deposition targets, and magnetron plasma sputter reactor assemblies.

### RELATED PATENT DATA

This patent claims continuation-in-part priority to PCT application serial number PCT/US01/45650, which was filed Oct. 9, 2001, and which claims priority to U.S. provisional application serial No. 60/306,836, which was filed Jul. 19, 2001. This patent also claims continuation-in-part priority to U.S. provisional application serial No. 60/493,183, which was filed Aug. 7, 2003.

### TECHNICAL FIELD

The invention pertains to methods of forming cast ingots, and also pertains to methods of forming high-purity metallic articles. Additionally, the invention pertains to methods of forming sputtering targets, and pertains to sputtering target constructions. Also, the invention pertains to sputter reactor assemblies. In particular aspects, the invention pertains to sputtering target constructions comprising, consisting essentially of, or consisting of, non-magnetic materials.

### BACKGROUND OF THE INVENTION

Physical vapor deposition (PVD) is a commonly used method for forming thin layers of material in semiconductor fabrication processes. PVD includes sputtering processes. In an exemplary PVD process, a cathodic target is exposed to a beam of high-intensity particles. As the high-intensity particles impact a surface of the target, they force materials to be ejected from the target surface. The materials can then settle on a semiconductor substrate to form a thin film of the materials across the substrate.

Difficulties are encountered during PVD processes in attempting to obtain a uniform film thickness across the various undulating features that can be associated with a semiconductor substrate surface. Attempts have been made to address such difficulties with target geometry. Accordingly, numerous target geometries are currently being commercially produced. Exemplary geometries are described with reference to FIGS. 1-8. FIGS. 1 and 2 illustrate an isometric view and cross-sectional side view, respectively, of an Applied Materials Self Ionized Plasma Plus™ target construction 10. FIGS. 3 and 4 illustrate an isometric view and cross-sectional side view, respectively, of a Novellus Hollow Cathode Magnetron™ target construction 12. FIGS. 5 and 6 illustrate an isometric and cross-sectional side view, respectively, of a Honeywell, International Endura™ target construction 14. Finally, FIGS. 7 and 8 illustrate an isometric and cross-sectional side view, respectively, of a flat target construction 16.

Each of the cross-sectional side views of FIGS. 2, 4, 6 and 8 is shown comprising horizontal dimensions “X” and vertical dimensions “Y”. The ratio of “Y” to “X” can determine if the target is a so-called three-dimensional target, or a two-dimensional target. Specifically, each of the targets will typically comprise a horizontal dimension “X” of from about 15 inches to about 17 inches. The Applied Materials™ target (FIG. 2) will typically comprise a vertical dimension “Y” of about five inches, the Novellus™ target (FIG. 4) will typically comprise a vertical dimension of about 10 inches, the Endura™ target (FIG. 6) will typically comprise a vertical dimension of from about two inches to about six inches, and the flat target will typically comprise a vertical dimension of less than or equal to about 1 inch. For purposes of interpreting this disclosure and the claims that follow, a target is considered to be a three dimensional target if the ratio of the vertical dimension “Y” to the horizontal dimension “X” is greater than or equal to 0.15. In particular aspects of the present invention, a three dimensional target can have a ratio of the vertical dimension “Y” to the horizontal dimension “X” of greater than or equal to 0.5. If the ratio of the vertical dimension “Y” to the horizontal dimension “X” is less than 0.15, the target is considered a two-dimensional target.

The Applied Materials™ target (FIG. 2) and Novellus™ target (FIG. 4) can be considered to comprise complex three dimensional geometries, in that it is difficult to fabricate monolithic targets having the geometries of such targets. The Applied Materials™ target (FIG. 2) and Novellus™ target (FIG. 4) both share the geometrical characteristic of comprising at least one cup 11 having a pair of opposing ends 13 and 15. End 15 is open and end 13 is closed. The cups 11 have hollows 19 extending therein. Further, each cup 11 has an internal (or interior) surface 21 defining a periphery of the hollow 19, and an exterior surface 23 in opposing relation to the interior surface. The exterior surface 23 extends around each cup 11, and wraps around the closed ends 13 at corners 25. Targets 10 and 12 each have a sidewall 27 defined by the exterior surface and extending between the ends 13 and 15. The targets of 10 and 12 of FIGS. 2 and 4 further share the characteristic of a flange 29 extending around the sidewall 27. A difference between the target 12 of FIG. 4 relative to the target 10 of FIG. 2 is that target 10 has a cavity 17 extending downwardly through a center of the target to narrow the cup 11 of target 10 relative to the cup of target 12.

Exemplary sputtering apparatuses which can utilize Applied Materials™ target 10 of FIG. 2 are described in U.S. Pat. No. 6,251,242. One of such apparatuses is shown diagrammatically in FIG. 9. Specifically, FIG. 9 illustrates a magnetron plasma sputter reactor 200 having sputtering target 10 provided therein. The target 10 will be described in FIG. 9 utilizing alternative language and numbering relative to that utilized in FIG. 2 in order to illustrate an alternative description of the target.

The reactor 200 comprises a magnetron 202 symmetrically arranged about a central axis 204. The target 10, or at least its interior surface, is composed of a material to be sputter-deposited. The target can comprise, for example, Ti, Ta or high purity copper. Target 10 comprises an annularly-shaped downwardly facing vault 206 (i.e., the hollow 19 described with reference to FIG. 2) facing a wafer 208 being sputter-coated. Vault 206 may be alternatively characterized as an annular downwardly facing trough. Vault 206 can have an aspect ratio of its depth to radial width of at least 1:2, and in particular applications, at least 1:1. The vault has an outer sidewall 210 outside of the outer periphery of the wafer 208, an inner sidewall 212 overlying the wafer 208, and a generally flat vault top wall or roof 216. Target 10 includes a central portion forming a post 218 including the inner sidewall 212 and a generally planar face 220 in parallel opposing relation to wafer 208. Flange 29 of target 10 forms a vacuum seal to a body 222 of reactor 200.

The magnetron reactor 200 includes one or more central magnets 224 having a first vertical magnetic polarization, and one or more outer magnets 226 of a second vertical magnetic polarization opposite the first polarization and arranged in an annular pattern. The magnets 224 and 226 can be permanent magnets, and accordingly can be composed of strongly ferromagnetic material. Inner magnets 224 are disposed within a cylindrical central well 228 (i.e., the cavity 17 of FIG. 2) formed between opposed portions of the inner target sidewall 212, and the outer magnets 226 are disposed generally radially outside of the outer target sidewall 210. A circular magnetic yoke 230 magnetically couples tops of the inner and outer magnets 224 and 226. The yoke can be composed of a magnetically soft material, such as, for example, a paramagnetic material, that can be magnetized to form a magnetic circuit for the magnetism produced by magnets 224 and 226.

A cylindrical inner pole piece 232 of magnetically soft material abuts the lower ends of inner magnets 224 and extends deep within target well 228 adjacent the inner target sidewall 212. Magnetic pieces 230 and 232 can be configured in size to emit a magnetic field (illustrated by dashed arrows within vault 206) that is substantially perpendicular to the magnetic field of the corresponding associated magnets 224 and 226. The magnetic field is, accordingly, also substantially perpendicular to the target vault sidewalls 210 and 212.

Reactor 200 includes a vacuum chamber body 222 which can have a dielectric target isolator (not shown) provided therein. Wafer 208 is clamped to a heater pedestal electrode 250 by appropriate mechanisms, such as, for example, a clamp ring (not shown). An electrically grounded shield (not shown) is typically provided to act as an anode with respect to the cathode target, and a power supply (not shown) is provided to negatively bias the cathode target. Various shields and power supplies which can be utilized with the apparatus of FIG. 9 are described in, for example, U.S. Pat. No. 6,251,242.

A port 252 is provided to extend through body 222, and a vacuum pumping system 254 is utilized to pump a vacuum within chamber 200 through port 252. An RF power supply 256 is utilized to RF bias pedestal 250, and a controller 258 is provided to regulate various aspects of apparatus 200, including, for example, the RF controller 256 and the vacuum pump 254, as shown.

It can be desired to form sputtering targets having a small average grain size. It is frequently found that targets having a smaller average grain size of the materials utilized therein will produce more uniform deposited films than will targets having the same materials with a larger grain size. A postulated mechanism for the effect of the smaller grain size on uniformity of deposited films is that small grain sizes can reduce micro-arcing problems relative to large grain sizes. The improvement in deposited film uniformity that can be achieved with materials having smaller grain sizes has led to a desire to incorporate small grain size materials into sputtering targets. It is found that small grain size materials can be formed within two-dimensional sputtering targets simply by subjecting the target materials to high compression during formation of the materials. Since the two-dimensional targets are essentially flat, high-compression technology can be readily incorporated into the processes of forming two dimensional targets. In contrast, it has proven difficult to form three dimensional targets having small grain sizes therein. It would be particularly desired to form monolithic copper targets having the complex geometries of the FIG. 2 and FIG. 4 target shapes, while also having a small average grain size.

Numerous materials can be utilized in forming sputtering targets, with exemplary materials being metallic materials (such as, for example, materials comprising one or more of Cu, Ni, Co, Mo, Ta, Al, and Ti), of which some materials can be non-magnetic. One of the materials that can be particularly desired for utilization in sputtering targets is high-purity copper (with the term “high purity” referring to a copper material having a purity of at least 99.995 weight percent). High-purity copper materials are frequently utilized in semiconductor fabrication processes for forming electrical interconnects associated with semiconductor circuitry. It would be desirable to develop processing which could form three-dimensional high-purity copper targets having an average grain size of less than or equal to about 250 microns.

### SUMMARY OF THE INVENTION

In one aspect, the invention encompasses a method of forming a metallic article, such as, for example, a sputtering target. The metal of the metallic article can comprise, for example, one or more of Cu, Ni, Co, Ta, Al, and Ti, and in particular embodiments can comprise Ta, Ti, or Cu. In a particular aspect, the invention encompasses a method of forming a high-purity copper article. An ingot of copper material is provided, with such ingot having a copper purity of at least 99.995 weight percent, and further having an initial grain size greater than 250 microns, and an initial thickness. The ingot is subjected to hot forging at a temperature of from about 700° F. to about 1,100° F. under sufficient pressure and time to reduce a thickness of the ingot by from about 40% to about 90% of the initial thickness. The product of the hot forging is quenched to fix an average grain size of less than 250 microns within the high-purity copper material. The average grain size can be fixed to be less than 200 microns, and even to be less than 100 microns. In particular aspects, the quenched material is formed into a three dimensional physical vapor deposition target.

In another aspect, the invention encompasses a method of forming a cast ingot. A mold is provided. Such mold has an interior cavity. The interior cavity is partially filled with a first charge of molten material. The first charge is cooled within the interior cavity to partially solidify such first charge. While the first charge of molten material is only partially solidified, a remaining portion of the interior cavity is at least partially filled with a second charge of the molten material. The first and second charges are cooled within the interior cavity to form an ingot comprising the first and second charges of the material. In particular aspects, the cast ingot is a high-purity copper material.

In yet another aspect, the invention encompasses various target constructions having particular geometries, and/or having an average grain size of less than about 250 microns.

In yet another aspect, the invention encompasses various monolithic copper target constructions in which the average grain size of the copper is less than 250 microns.

### BRIEF DESCRIPTION OF THE DRAWINGS

Preferred embodiments of the invention are described below with reference to the following accompanying drawings.

FIG. 1 is an isometric view of a prior art Applied Materials™ sputtering target.

FIG. 2 is a cross-sectional side view of the sputtering target of FIG. 1.

FIG. 3 is an isometric view of a prior art Novellus™ hollow cathode sputtering target.

FIG. 4 is a cross-sectional side view of the FIG. 3 sputtering target.

FIG. 5 is an isometric view of a prior art Honeywell International Endura™ sputtering target.

FIG. 6 is a cross-sectional side view of the FIG. 5 sputtering target.

FIG. 7 is an isometric view of a prior art flat sputtering target.

FIG. 8 is a cross-sectional side view of the FIG. 7 sputtering target.

FIG. 9 is diagrammatic, cross-sectional view of a prior art magnetron sputter reactor.

FIG. 10 is an isometric view of an ingot at a preliminary processing step of a method of the present invention.

FIG. 11 is a view of the ingot of FIG. 10 being compressed by a hot forge.

FIG. 12 is a view of a hot forge product resulting from the hot forge compression of FIG. 11.

FIG. 13 is a cross-sectional side view through the product of FIG. 12, illustrating a three dimensional target profile that can be machined from the product of FIG. 12.

FIG. 14 is a view of the FIG. 12 product placed within a press configured for formation of a three dimensional target shape from the FIG. 12 product.

FIG. 15 is a view of the FIG. 14 apparatus shown at a processing step subsequent to that of FIG. 14, and illustrating a three dimensional target shape formed from the FIG. 12 hot forge product.

FIG. 16 is a diagrammatic, cross-sectional view of a first embodiment sputtering target geometry encompassed by the present invention.

FIG. 17 is a diagrammatic, cross-sectional view of a second embodiment sputtering target geometry encompassed by the present invention.

FIG. 18 is a diagrammatic, cross-sectional view of a third embodiment sputtering target geometry encompassed by the present invention.

FIG. 19 is diagrammatic, cross-sectional view of a magnetron sputter reactor comprising the first embodiment sputtering target geometry encompassed by the present invention.

FIG. 20 is a diagrammatic, cross-sectional view through a prior art cast ingot.

FIG. 21 is a diagrammatic, cross-sectional view of an apparatus utilized in forming a cast ingot in accordance with a method of the present invention.

FIG. 22 is a view of the FIG. 21 apparatus shown at a processing step subsequent to that of FIG. 21.

FIG. 23 is a view of the FIG. 21 apparatus shown at a processing step subsequent to that of FIG. 22.

FIG. 24 is a diagrammatic cross-sectional side view of a cast ingot formed in accordance with methodology of the present invention.

### DETAILED DESCRIPTION OF THE PREFERRED EMBODIMENTS

In one aspect, the invention encompasses a method of forming a metallic article having a grain size of less than about 250 μm, preferably less than about 200 μm, and even more preferably less than about 100 μm. Such embodiment is described with reference to FIGS. 10-15. Referring initially to FIG. 10, an ingot 20 of metallic material is illustrated. Ingot 20 can, in particular embodiments, comprise a cast material. Exemplary metallic components of ingot 20 are one or more of Cu, Ni, Co, Ta, Al, and Ti; with a suitable material being copper having a purity of at least 99.995 weight percent. The metallic materials can include alloys which include one or more of Cu, Ni, Co, Ta, Al, and Ti; such as, for example, a Ti/Zr alloy having a purity of at least 99.9995 weight percent. Ingot 20 comprises a substantially cylindrical shape with a diameter “D” and a thickness “T”. Thickness “T” can be referred to as an initial thickness of ingot 20. The shape of ingot 20 is referred to as a “substantially” cylindrical shape to indicate that there may be minor deviation of the shape from a true cylinder. Ingot 20 further comprises opposing ends 22 and 24. End 22 can be referred to as a first end, and end 24 can be referred to as a second end.

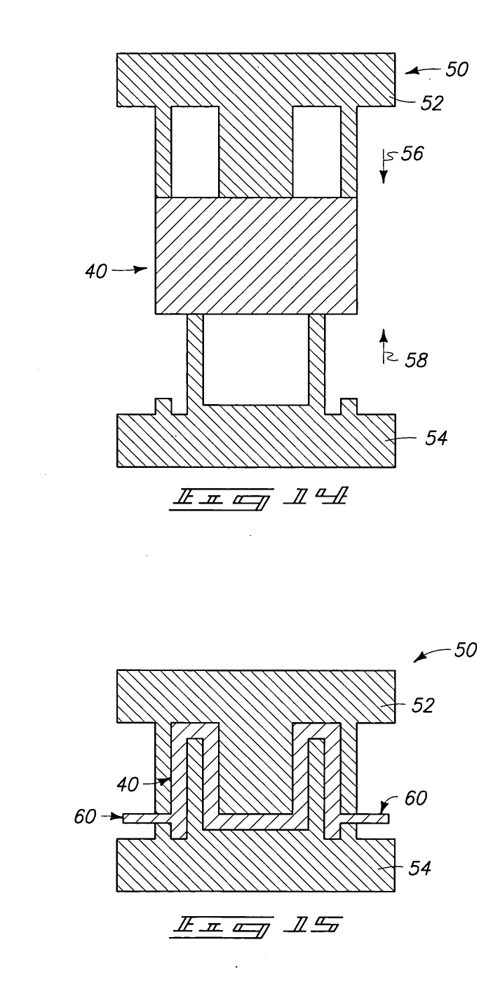

Referring to FIG. 11, ingot 20 is placed within a forging apparatus 30. Apparatus 30 can be considered to be a hot forge, in that it is preferably configured to compress ingot 20 while the ingot is at a temperature higher than room temperature. Ingot 20 will be typically be compressed while a bulk of the ingot is at a temperature of from about 700° F. to about 1,100° F., and more preferably, while the bulk of the ingot is at a temperature of from about 850° F. to about 1,050° F., (with the term “bulk” meaning greater than or equal to 95% of a mass of the ingot).

Apparatus 30 can be considered to comprise a press configured to press against the opposing ends 22 and 24 of ingot 20. Apparatus 30 comprises a first portion 32, and an opposing second portion 34. In operation, ingot 20 is placed between portions 32 and 34, with first end 22 proximate and facing first portion 32, and second end 24 proximate and facing second portion 34. Portions 32 and 34 are then displaced relative to one another to compress ingot 20 between them. The displacement of portions 32 and 34 is illustrated by arrow 37 in FIG. 11, with such arrow indicating that portion 32 is moved toward portion 34. It is to be understood that the displacement of portions 32 and 34 can alternatively comprise movement of portion 34 toward portion 32, or can comprise movement of both of portions 32 and 34 toward one another. The compression of ingot 20 is preferably under sufficient pressure, and for a sufficient duration of time, to reduce a thickness of the ingot by from about 40% to about 90% of the initial thickness, (i.e., to reduce the ingot to a thickness that is from about 10% to about 60% of the initial thickness).

The hot forging converts ingot 20 into a hot-forged product (shown in FIG. 12). A suitable pressure for compression of ingot 20 is less than or equal to about 10,000 pounds per square inch (psi), with an exemplary pressure being about 9,700 psi. In a particular process of the present invention, ingot 20 will have a diameter “D” of about 10 inches, and a pressure of about 1,100 tons will be applied across an entirety of the surfaces of ends 22 and 24.

Ingot 20 will typically initially comprise an average grain size of about 10,000 μm if the ingot is a cast material, and such grain size can be reduced to less than or equal to 250 μm , 200 μm , or even 100 μm with hot-forging of the present invention. For instance, in an exemplary process in which a thickness of a high purity copper ingot 20 is reduced to about 30% of an initial thickness in a time of less than about one hour, the resulting hot-forged product had a measured average grain size of from about 85 microns to 90 microns after quenching to a temperature of about 70° F.

Among the parameters that can affect a grain size ultimately formed within the hot-forged product obtained by the compression of FIG. 11 is a duration of the compression. Specifically, it can be preferred that ingot 20 be subjected to the relatively high temperatures associated with the hot-forging for a period of time of from about 15 minutes to about three hours, and preferably from about 30 minutes to about one hour. Also, the amount of reduction of the thickness of ingot 20 can have an effect on the resulting average grain size. Specifically, it is found that if the thickness of ingot 20 is reduced by less than 60%, a resulting grain size can increase beyond 100 μm. For instance, it has been found that if the thickness of a high purity copper material is reduced by 50%, a resulting grain size is 200 μm, while a thickness reduction by from about 60% to 90% can achieve a resulting average grain size of about 100 μm or less. The temperatures associated with hot forging can include a step of heating the ingot 20 to a desired temperature of greater than 700° F. (preferably greater than 800° F) in an oven, and then hot pressing the ingot 20 while maintaining the temperature of the bulk of the ingot 20 (with the “bulk” of the ingot being considered to be greater than or equal to about 95% of the mass of the ingot) at greater than 700° F. (preferably greater than 800° F.). The duration of the hot forging temperature is considered to include the time that the ingot 20 is in the oven at the desired temperature, as well as the time that the ingot is being hot pressed at the desired temperature.

In the shown preferred embodiment, lubricating materials 36 and 38 are provided between ingot 20 and the portions 32 and 34, respectively, of apparatus 30. Lubricating materials 36 and 38 preferably comprise a solid lubricant, such as, for example, graphite foil. The solid lubricant can be preferred over liquid lubricants, as solid lubricants are found to be more suitable for the high temperatures employed in the hot forging process of the present invention. In less preferred embodiments, liquid lubricants can be utilized. However, it is found that liquid lubricants typically burn under the processing conditions of the present invention.

The graphite foil 36 is preferably provided to a thickness of from about 0.01 inches to about 0.100 inches, with a preferred thickness being from about 0.030 inches to about 0.060 inches. Graphite foil 38 has similar preferred thickness ranges. It is found that if either graphite foil 36 or foil 38 is thinner than 0.01 inches, it tears during processing of the present invention, and if the foil is thicker than 0.100 inches it can interfere with the forging process by contributing its own mechanical properties to the processing. Such contribution of mechanical properties of the lubricating foil to the processing can disrupt reproducibility of the processing conditions, and further can cause an average grain size associated with the ends of ingot 20 to be different than an average grain size within an interior region (i.e., a region between the ends) of ingot 20. The graphite foil can be provided to a desired thickness by stacking several thin sheets of graphite foil on top of one another to achieve the thickness of from about 0.030 inches to about 0.060 inches. Alternatively, a single sheet of solid lubricant having the desired thickness can be utilized.

After the compression of ingot 20 within apparatus 30, the resulting hot-forged product is quenched to fix an average grain size of less than 250 μm, 200 μm, or even 100 μm within the product. The term “fix” is used to indicate that the average grain size stops changing within the material after the quench, and more specifically, that the average grain size remains fixed within the material provided that the material is kept at temperatures below 100° F. If the material is reheated to temperatures above 100° F., and particularly to temperatures in excess of 150° F., an average grain size within the material can begin to increase. The quenching of the hot-forged product typically occurs within about 15 minutes of removing the hot-forged product from press 30, and typically comprises reducing a temperature of an entirety of the hot-forged product to less than or equal to about 150° F. Such can be accomplished by immersing the hot-forged product within a tank of fluid maintained at about room temperature (about 70° F.). In preferred embodiments of the present invention, an entirety of the hot-forged product is reduced to a temperature of less than or equal to about 70° F. within about 15 minutes of removing the hot-forged product from press 30.

FIG. 12 illustrates a hot-forged product resulting from compression of ingot 20 (FIG. 10) within apparatus 30 (FIG. 11). Product 40 comprises a substantially cylindrical shape having a diameter “E” and a thickness “W”. Thickness “W” is preferably from about 10% to about 40% of the original thickness “T” of ingot 20 (FIG. 10). Product 40 comprises the opposing ends 22 and 24 of ingot 20, with such ends now having a diameter “E” which is larger than the diameter “D” of ingot 20.

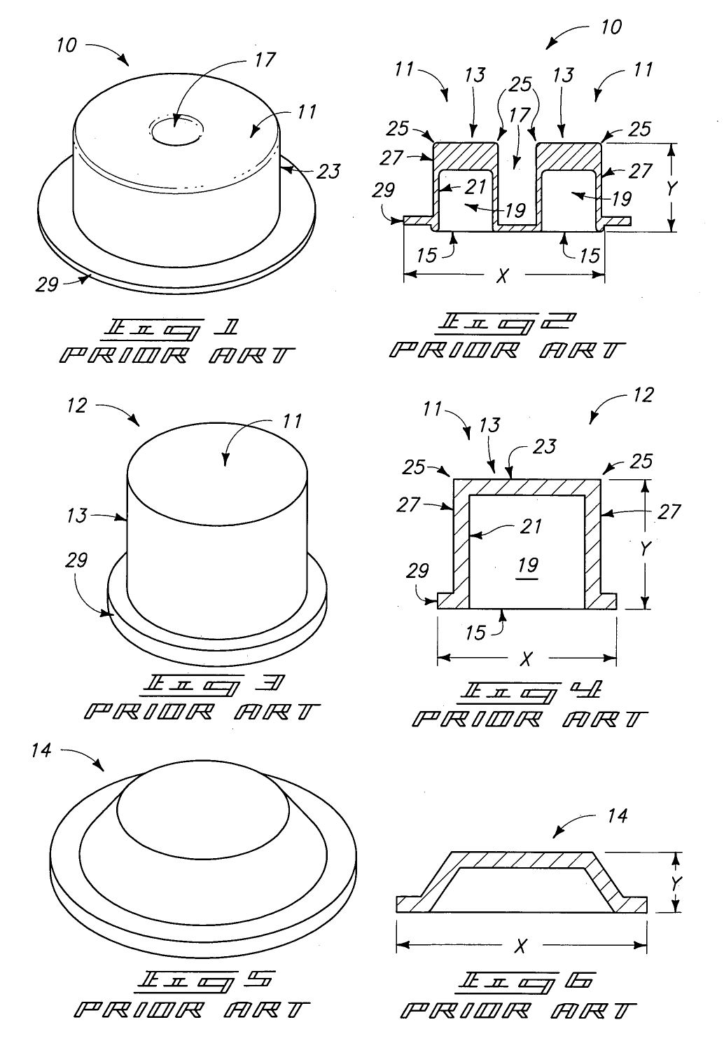

Hot-forged product 40 can be formed into a sputtering target. An exemplary method of forming product 40 into a sputtering target is described with reference to FIG. 13. Specifically, product 40 is shown in cross-sectional side view, and a target construction 42 is illustrated contained within product 40. Target construction 42 corresponds approximately to the three dimensional target 10 of FIGS. 1 and 2. It is to be understood, however, that target construction 42 can correspond to other constructions, such as, for example, a two dimensional target construction, or the three dimensional target constructions 12 and 14 of FIGS. 3-6. Product 40 comprises a mass of material 44 surrounding the target construction 42. Mass 44 can be removed by machining processes to leave the target construction 42.

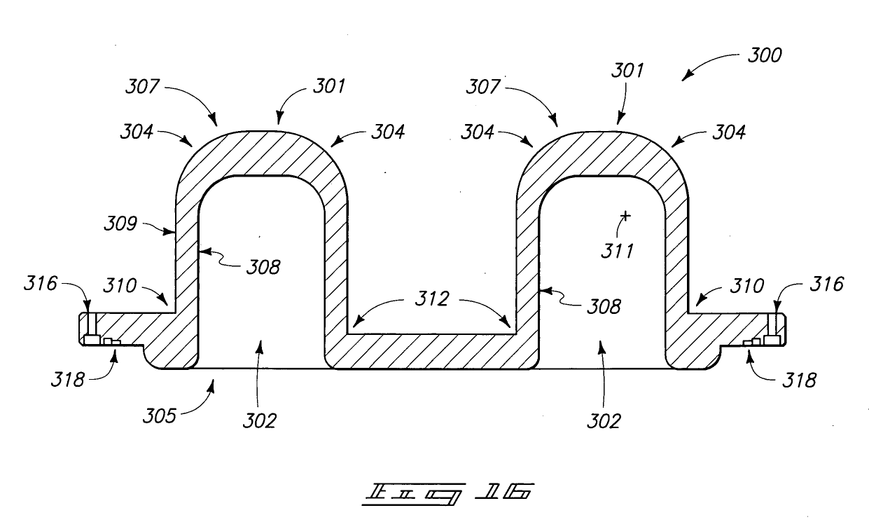

Another method for forming a target construction from product 40 is described with reference to FIGS. 14 and 15. Referring initially to FIG. 14, hot-forged product 40 is provided within a press 50. Press 50 comprises a first portion 52 and a second portion 54. Portions 52 and 54 are displaced relative to one another to compress product 40 between them. In the shown embodiment, the displacement of portions 52 and 54 is illustrated by arrows 56 and 58, which indicate that both of portions 52 and 54 are moved relative to one another. It is to be understood, however, that the invention encompasses other embodiments wherein only one of portions 52 and 54 is moved during the displacement of portions 52 and 54 relative to one another.

FIG. 15 illustrates apparatus 50 after product 40 is compressed between portions 52 and 54. Product 40 is shown molded into a three dimensional target configuration corresponding approximately to the shape of target 10 (FIGS. 1 and 2). It is noted that product 40 is not exactly in the shape of target 10, and the shown embodiment excess material 60 is shown extruding outwardly from sides of the target material. Such excess material can be removed by appropriate machining. Also, to any other extent that product 40 is not formed exactly into a desired target shape, the product can be machined to refine a shape of the product into a desired target shape. Generally, press 50 will not be utilized to form target 40 into an exact target shape, but rather will be utilized to form target 40 into a shape which approximates the desired target shape, with excess material remaining over that of the desired target shape. The excess material is then removed by appropriate machining to form the desired target shape.

Press 50 is preferably operated under conditions in which product 40 is held within a temperature range of from about 1,300° F. to about 1,700° F. for a duration of time of less than or equal to about five minutes, and preferably of less than or equal to about three minutes, to allow the material of product 40 to extrude into the desired target shape. Product 40 can be initially pre-heated in an oven to a temperature greater than 1,300° F., and then subject to pressing within press 50. The oven pre-heating is generally preferred, as it is typically not practical to heat product 40 to a desired temperature in excess of 1,300° F. with press 50 alone.

After the material of product 40 is compressed into the desired target shape by press 50, it can be quenched under identical conditions to those discussed above for hot quenching of a forged product from apparatus 30 (FIG. 11). Accordingly, the target shape resulting from compression of product 40 within press 50 can be quenched such that an entirety of the target shape is reduced to a temperature of less than or equal to about 150° F. (and preferably less than or equal to about 70° F.) within about 15 minutes of removing the target shape from within press 50.

An advantage of utilizing the embodiment of FIGS. 14 and 15, relative to that discussed above with reference to FIG. 13, is that the embodiment of FIGS. 14 and 15 can comprise less waste of material than does that of FIG. 13. A hot-forged product utilized in the embodiment of FIG. 13 will typically comprise a shape of about five inches in thickness by about 17 inches in diameter, whereas that utilized for the embodiment of FIGS. 14 and 15 can be smaller, and in particular embodiments can be on the order of about four inches in thickness by about 15 inches in diameter to form the same product as that formed by a material having five inches in thickness and 17 inches in diameter and subjected to the FIG. 13 processing. This can enable about a 40% to 50% reduction in material processed according to the embodiment of FIGS. 14 and 15, relative to the material processed according to the embodiment of FIG. 13. For instance, a high-purity copper material subjected to processing to form a three dimensional target can comprise a mass of several hundred pounds when utilized to form three dimensional sputtering targets. The utilization of the embodiment of FIGS. 14 and 15 has been found to save about 180 pounds of copper material relative to the utilization of the embodiment of FIG. 13.

A lubricant can be applied to surfaces of product 40 during the processing of FIGS. 14 and 15. A preferred lubricant can be a liquid lubricant, in spite of the high temperatures utilized during such processing, because a liquid lubricant can flow within the various undulations of press 50 better than a solid lubricant. In particular embodiments, a high temperature cooking oil is utilized as the lubricant.

The methodology of FIGS. 14 and 15 can be utilized to form numerous complex target geometries. Exemplary target geometries are described with reference to FIGS. 16-18. Referring initially to FIG. 16, a target 300 is illustrated. Target 300 comprises a geometry similar to that of the target 10 of FIG. 2 (i.e., geometry similar to an Applied Materials™ target). Target 300 comprises a shape which includes a cup 301 having a hollow 302 extending therein. An interior surface 308 defines a periphery of the hollow, and an exterior surface 309 is in opposing relation to the interior surface. Cup 301 has a first end 305 and an opposing second end 307. End 305 is open, and in the shown embodiment end 307 is closed. It is to be understood, however, that end 307 could comprise an opening extending therethrough.

Exterior surface 309 extends around end 307 (in the shown embodiment the exterior surface extends entirely around the closed end, but it is to be understood that the invention encompasses other embodiments (not shown) wherein the exterior surface extends only partially around an open end 307). Exterior surface 309 wraps around end 307 at rounded corners 304. Such rounded corners have a radius of curvature about a point (with an exemplary point 311 illustrated) of at least about 1 inch. In particular embodiments, the radius of curvature around corners 304 can be at least about 1.25 inches, 1.5 inches, 1.75 inches, 2 inches, or greater. It is preferred that the radius of curvature be small enough to avoid excess thinning of the target material at locations proximate curved regions 304. Excess thinning can be understood as thinning which detrimentally influences target performance.

Target 300 can comprise an inner shape defined by peripheral surface 308 which is substantially identical to, or in particular embodiments exactly identical to, a prior art Applied Materials™ target; and yet comprises an outer shape defined by peripheral surface 309 which is different than the prior Applied Materials™ target.

An advantage of forming curved corners 304 is that such can simplify the process of FIGS. 14 and 15 relative to formation of more square or angled corners. Specifically, it is found that the compression within press 50 of FIGS. 14 and 15 can be difficult relative to substantially square corners, in that there can be poor material flow around such square corners. However, utilization of curved corners can enhance material flow, and thus improve the quality of a product formed by the compression of FIGS. 14 and 15. It is noted that although only some of the square corners associated with the external periphery 309 of target 300 have been rounded, other corners (such as, for example, the corners labeled as 310 and 312) can be rounded in other embodiments of the invention. An advantage of not rounding corners 310 and 312 can be that a target apparatus comprising substantially square corners 310 and 312 will fit within a prior art Applied Materials™ sputtering apparatus without modification to either the target or the apparatus. An advantage of rounding at least some of the corners of a three-dimensional target construction is that such can reduce an amount of material incorporated into the target construction, and thus reduce an expense associated with the material of the target construction.

The shown target has orifices 316 extending through flanges 318, and configured for attaching the target to a sputtering apparatus. It is to be understood, however, that the illustrated flanges 318 and orifices 316 are exemplary, and that other configurations can be utilized in target constructions of the present invention.

Target 300 can consist essentially of a material which comprises one or more of Ni, Co, Ta, Al, and Ti; and in particular embodiments that material can consist essentially of Cu or Ti.

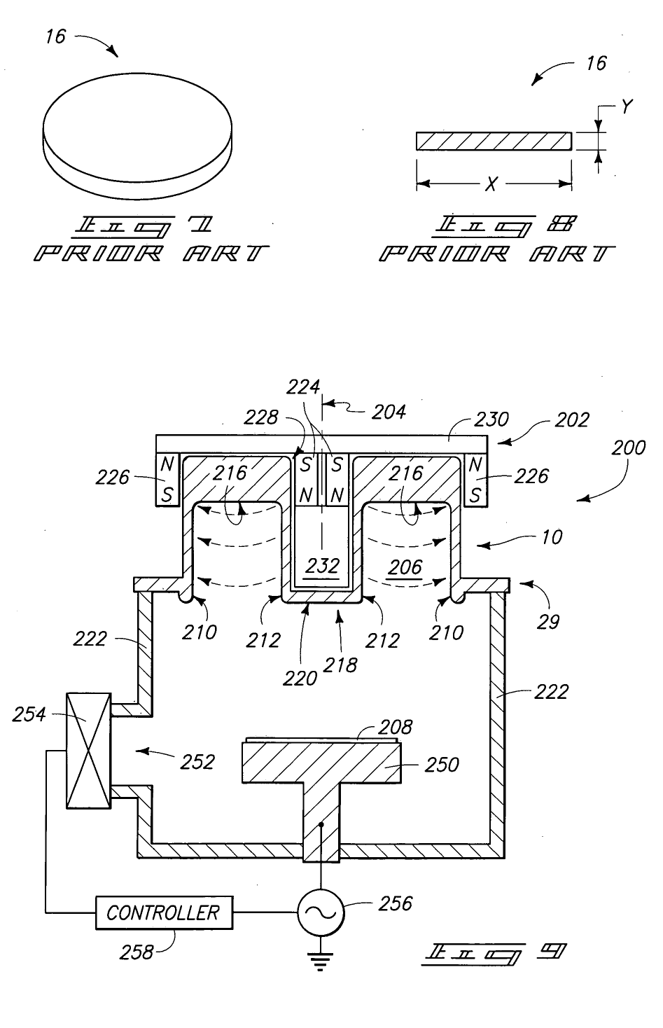

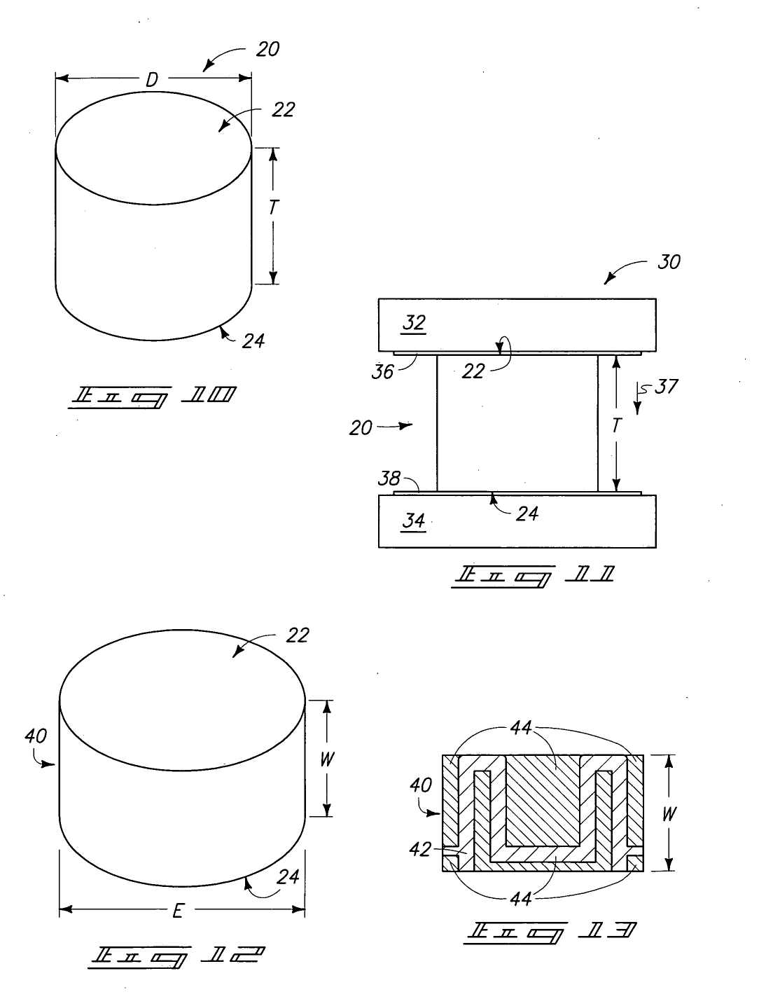

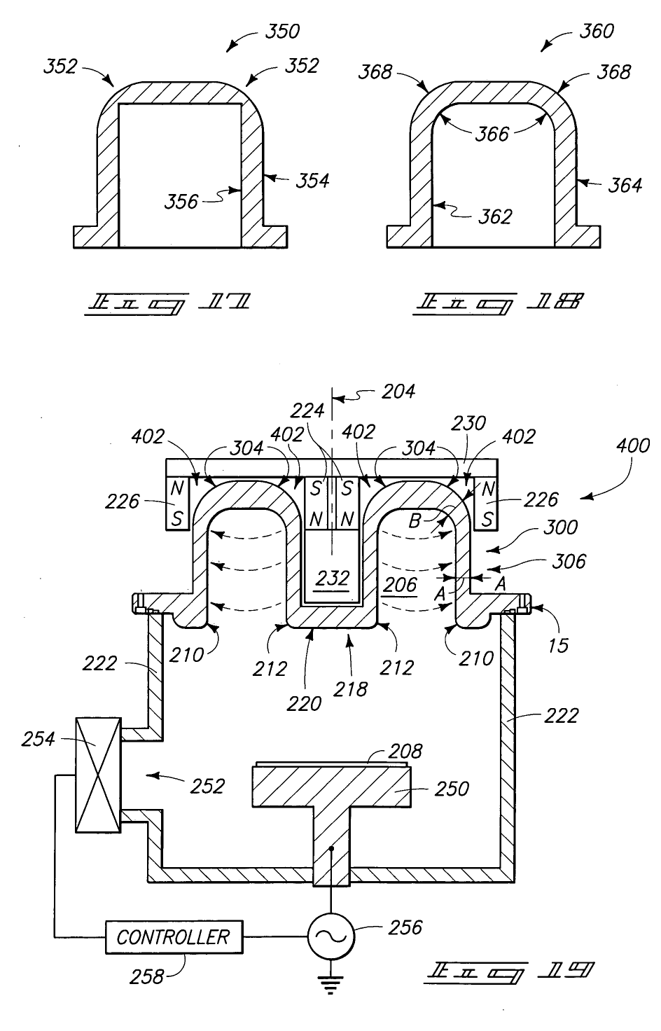

FIGS. 17 and 18 show additional embodiments of target constructions that can be formed in accordance with the present invention. Specifically, FIG. 17 shows a target 350 similar to the Novellus™ target of FIG. 4, but having rounded corners 352 along an outer periphery 354 of the target. The target 350 comprises an inner periphery 356 which is identical to the inner periphery of the prior art Novellus™ target. A radius of curvature of rounded corners 352 can be identical to the radius described above with reference to target 300 of FIG. 16.

Referring to FIG. 18, a target 360 is illustrated. Target 360 is also similar to the Novellus™ target of FIG. 4, but comprises rounded corners along an inner periphery 362, as well as along an outer periphery 364. More specifically, inner periphery 362 comprises rounded corners 366 and outer periphery 364 comprises rounded corners 368. In the shown embodiment, rounded corners 368 and 366 comprise a same radius of curvature as one another; and interior rounded corners 366 are radially within exterior rounded corners 368. The radius of curvature of corners 366 and 368 can be, for example, identical to that described previously with reference to FIG. 16. It is to be understood that the invention encompasses other embodiments (not shown) wherein inner corners 366 comprise a different radius of curvature than outer corners 368.

Referring to FIG. 19, a magnetron sputter reactor 400 is illustrated to comprise a target 300 of the type described with reference to FIG. 16. Similar numbering will be utilized in describing reactor to 400 as was used above in describing the reactor 200 of FIG. 9, where appropriate. Reactor 400 comprises magnets 226 and 224. A difference between the utilization of target 300 versus target 10 (FIG. 9) is that curved corners 304 cause gaps 402 to occur between outer periphery 306 of target 300 and the magnets 224 and 226. Gaps 402 are generally not problematic, in that a magnetic permeability associated with the gaps does not appreciably affect the magnetic flux through the material of target 300. It can, however, be problematic to have a target 300 with a different thickness in between a magnet and sputtering surface at one portion of a cup shape of the magnet than within another portion of the cup shape of the magnet. For instance, the shown target 300 has a first thickness “A” extending through a lower portion of a sidewall, and a second, larger thickness, “B” extending through a second portion of sidewall. The relative ratio of “A” to “B” can cause different magnetic permeabilities associated with different portions of the target, and thus alter sputtering performance of one portion of the target relative to another. However, in embodiments in which the target comprises non-magnetic materials (such as, for example, copper), there can be negligible effect from having different thicknesses around the cup of the target construction. In embodiments in which the different thicknesses of the target construction are found to be problematic, a target construction can be formed having curved corners, with a radius of curvature and geometrical proportion being chosen to minimize or eliminate differences in magnetic flux associated with different regions of the target during a sputtering operation.

A difficulty which has been found in utilizing the processing of FIGS. 10-19 is in obtaining a suitable starting ingot for the processing. FIG. 20 illustrates a prior art ingot 70 in cross-sectional view, and shows a problem with conventional casting processes. Specifically, ingot 70 comprises a thickness “R”, and a shrinkage cavity 72 extending a significant depth into the ingot material to reduce a usable amount of the thickness “R”. A dashed line 74 is shown across ingot 70 to divide the ingot into an unusable portion 76 above the dashed line and a usable portion 78 below the dashed line. In practice, ingot 70 would be cut along dashed line 74, and accordingly the thickness would be reduced to a second thickness “X” which corresponds to the thickness of usable portion 78 of the ingot. In traditional casting processes, a high purity copper ingot 70 formed with an initial thickness “R” of about 15 inches will have a shrinkage cavity 72 typically extending to a thickness of greater than two inches. Such shrinkage cavity will reduce the usable portion of ingot 70 to a thickness “X” of less than about 13 inches. In other words, at least about 13% of the original thickness “R” is sacrificed due to the shrinkage defect 72.

Shrinkage defect 72 occurs during cooling of the material of ingot 70 in a casting process. In applications of the present invention, it can be preferred that an ingot have a usable portion which is at least 14 inches in thickness, and in some applications it can be desired that the ingot initially be about 17 inches in usable thickness. One method of achieving such ingots would be to initially form ingots which are much thicker than is desired, and to then cut a significant amount of the ingot away to remove a shrinkage defect. However, it would be preferred to develop methods of forming ingots which substantially alleviate the formation of a shrinkage defect within the ingots.

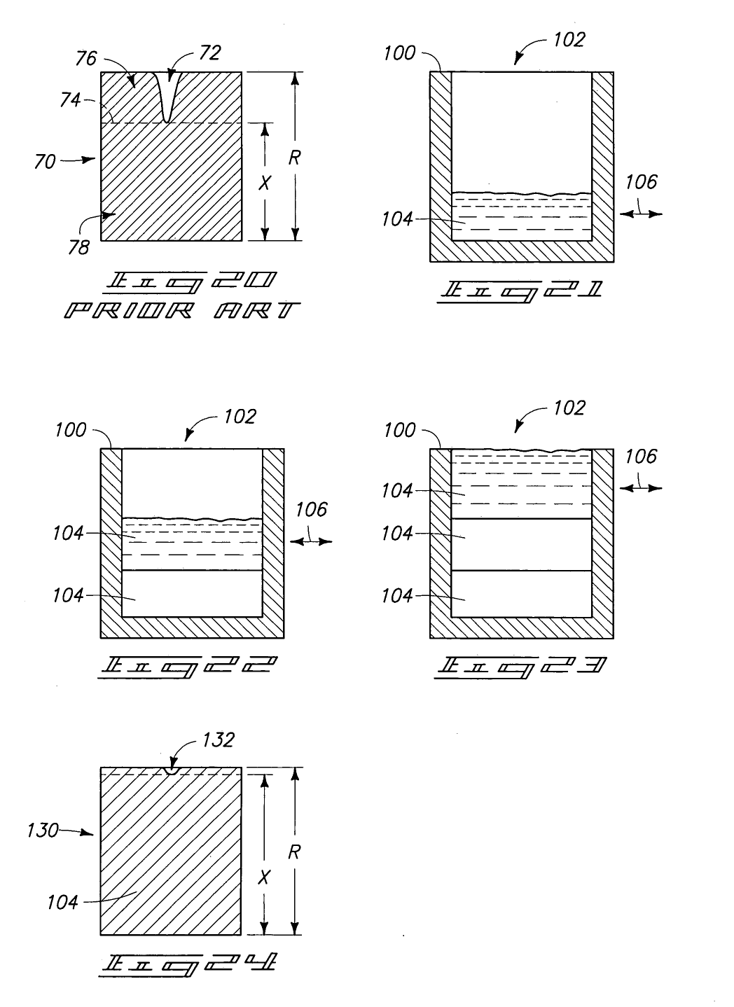

A method of forming ingots in accordance with the present invention is described with reference to FIGS. 21-24. Referring initially to FIG. 21, a mold 100 is shown in cross-sectional view. Mold 100 comprises an interior cavity 102 which, in preferred embodiments, can comprise a cylindrical shape. A first charge of a molten metallic material 104 is provided within cavity 102 to only partially fill the cavity. In a preferred embodiment, the first charge will be provided to fill less than or equal to about 50% of the volume of interior cavity 102. Material 104 is cooled while agitating mold 100. The agitation is preferably a mechanical agitation, as illustrated by the arrow 106. The agitation can be in the side-to-side motion shown, or can comprise other motions. The agitation helps to expel gas from within molten material 104 during the cooling of the material. In a particular embodiment, material 104 comprises high-purity copper initially provided within mold 100 at a temperature of from about 2200° F. to about 2800° F., and mold 100 is held at a cooling temperature less than a melting point of material 104. Material 104 is allowed to cool for a time of from about 30 seconds to about 40 seconds, so that an upper surface of material 104 becomes partially solidified.

Referring to FIG. 22, a second charge of material 104 is provided over the partially solidified first charge. Mold 100 is then agitated while second charge 104 is allowed to cool for from about 30 seconds to about 40 seconds.

Referring to FIG. 23, a third charge of material 104 is provided over the second charge, and mold 100 is agitated while the first, second and third charges completely cool and solidify. A reason for having the earlier charges of material 104 only partially solidified during addition of the later charges is to avoid forming a solid interface between the various charges. Although FIGS. 22 and 23 show interfaces between the first, second and third charges, such are provided for illustration purposes only, and in practice such interfaces are avoided by having the various charges only partially solidified. Accordingly, the resulting ingot has a homogeneous composition from a lowermost portion of the ingot to an uppermost portion.

FIG. 24 illustrates a cross-sectional side view of an ingot 130 formed in accordance with the present invention. Ingot 130 comprises a thickness “R”, and a shrinkage cavity 132 extending partially along the thickness “R”. However, shrinkage cavity 132 is significantly smaller than the shrinkage cavity 72 of the prior art ingot 70 shown in FIG. 20. Accordingly, a usable portion “X” of ingot 130 is much larger than the usable portion “X” of the prior art ingot 70. In particular applications, ingots have been formed having a cavity depth of less than 0.25 inches in a total thickness “R” of 15 inches, and also having a cavity depth of less than 0.25 inches in a total thickness of 18 inches. Accordingly, ingot 130 can be formed to have a shrinkage cavity that extends to less than or equal to about 10% of a total thickness “R” of the ingot, and in particular embodiments to less than or equal to about 5% of a total thickness “R” of the ingot, and in yet other embodiments to less than or equal to about 2% of a total thickness “R” of the ingot.

In particular embodiments, each of the successive charges of molten material provided within interior cavity 102 after the first charge fill a volume corresponding to about 10% of the original volume of the interior cavity. Accordingly, if a first charge fills about 50% of a volume of the original cavity, each additional charge will fill about 10% of such volume of the original cavity, and there will be about five such additional charges utilized to entirely fill the ingot mold. In another particular embodiment, a first charge fills about 90% of the original volume of the interior cavity, and the remaining volume is filled with a single subsequent charge. The casting of the present invention can comprise vacuum casting which is performed in a vacuum chamber and under a pressure of about 200 mTorr.

Methodology of the present invention can be utilized to form three-dimensional targets having an average grain size of less than or equal to 250 microns, 200 microns, or even 100 microns. For instance, methodology of the present invention can be utilized to form monolithic copper targets having a copper purity of at least 99.995 weight percent, and having complex three dimensional shapes of the types exemplified in FIGS. 2 and 4. As another example, methodology of the present invention can be utilized to form monolithic targets comprising Ta or Ti, and having complex three dimensional shapes of the types exemplified in FIGS. 2 and 4.

Although particular metals and alloys are described above for the exemplary aspects of the invention being discussed, it is to be understood that any suitable composition can be utilized in the methodology and target constructions of the present invention. Among the numerous alloys and metal-containing compositions that can be utilized are compositions comprise copper together with one or more of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, and Hf. Exemplary compositions can consist essentially of less than or equal to about 99.99% copper by weight and at least one element selected from the group consisting of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, Sn and Hf. In particular instances, the at least one element can preferably be selected from Ag, Al, In, Zn, B, Ga, Mn, Sn, Ge, Ti and Zr. A total amount of the at least one element present in the constructions can preferably be from at least about 100 ppm by weight to less than about 10% by weight. More preferably, the at least one element can be present at from at least 1000 ppm to less than about 2%, by weight. Typically the at least one element will be present to about 0.5 atomic percent.

A specific composition which can be utilized in the various targets described herein is a composition comprising, consisting essentially of, or consisting of CuSn, with the Sn being present to from about 100 ppm (by weight) to about 3 atomic percent, and with a typically amount of Sn being about 0.5 atomic percent.

Another specific composition which can be utilized in the various targets described herein is a composition comprising, consisting essentially of, or consisting of CuAl, with the Al being present to from about 100 ppm (by weight) to about 3 atomic percent, and with a typically amount of Al being about 0.5 atomic percent.

Another specific composition which can be utilized in the various targets described herein is a composition comprising, consisting essentially of, or consisting of CuAg, with the Ag being present to from about 100 ppm (by weight) to about 3 atomic percent, and with a typically amount of Ag being about 0.5 atomic percent.

1. A method of forming a metallic article, comprising:
providing an ingot of metallic material; the ingot having an initial grain size greater than 250 microns, and an initial thickness;
subjecting the ingot to hot forging at a temperature of from about 700° F. to about 1100° F. under sufficient pressure and time to reduce a thickness of the ingot to from about 10% to about 60% of the initial thickness; the hot forging converting the ingot into a hot-forged product;
quenching the hot-forged product to fix an average grain size less than 250 microns within the metallic material; the quenched material being a metallic article;
wherein the hot forging is conducted in a press;
wherein the hot-forged product is removed from the press after the hot forging; and
wherein the quenching comprises reducing a temperature of an entirety of the hot-forged product to less than or equal to about 150° F. within about 15 minutes of removing the hot-forged product from the press.

2. The method of claim 1 wherein the metallic material comprises copper having a purity of at least 99.995 weight percent.

3. The method of claim 1 wherein the metallic material comprises one or more of Ni, Co, Ta, Al, and Ti.

4. The method of claim 1 wherein the metallic material comprises copper together with one or more of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, and Hf.

5. The method of claim 1 wherein the metallic material consists essentially of copper and at least one element selected from the group consisting of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, Sn and Hf; and wherein the copper is present to a concentration of less than or equal to about 99.99%, by weight.

6. The method of claim 5 wherein the at least one element is selected from the group consisting of Ag, Al, In, Zn, B, Ga, Mn, Sn, Ge, Ti and Zr.

7. The method of claim 5 wherein a total amount of the at least one element is from at least about 100 ppm to less than about 10%, by weight.

8. The method of claim 5 wherein a total amount of the at least one element is from at least 1000 ppm to less than about 2%, by weight.

9. The method of claim 1 wherein the metallic material consists essentially of CuSn, with the Sn being present to from about 100 ppm, by weight, to about 3 atomic percent.

10. The method of claim 1 wherein the metallic material consists essentially of CuAl, with the Al being present to from about 100 ppm, by weight, to about 3 atomic percent.

11. The method of claim 1 wherein the metallic material consists essentially of CuAg, with the Ag being present to from about 100 ppm, by weight, to about 3 atomic percent.

12. The method of claim 1 wherein the fixed average grain size is less than 200 microns.

13. The method of claim 1 wherein the fixed average grain size is less than 100 microns.

14. The method of claim 1 further comprising forming the metallic article into a physical vapor deposition target.

15. The method of claim 1 further comprising forming the metallic article into a three-dimensional physical vapor deposition target, the forming metallic article into a three-dimensional physical vapor deposition target comprising:
providing the press to have a first portion receivable within a second portion;
positioning the metallic article between the first and second portions of the press; and
pressing the metallic article between the first and second portions to shape the metallic article into about the shape of the three-dimensional physical vapor deposition target.

16. A method of forming a cast ingot, comprising:
providing a mold having an interior cavity;
partially filling the interior cavity with a first charge of molten metallic material to leave a remaining unfilled portion of the interior cavity;
cooling the first charge of molten material within the interior cavity to partially solidify the first charge of molten material; the first charge being agitated within the interior cavity during at least some of the cooling;
while the first charge of molten material is only partially solidified, at least partially filling the remaining unfilled portion of the cavity with a second charge of the molten material; and
cooling the first and second charges of the molten material within the interior cavity to form an ingot comprising the first and second charges of material; the second charge being agitated within the interior cavity during at least some of the cooling of the second charge.

17. The method of claim 16 wherein the ingot has a cylindrical shape comprising a thickness and a diameter; and wherein any shrinkage cavity formed in a top of the ingot during the casting process has a depth less than 10% of the thickness of the cylindrically-shaped ingot.

18. The method of claim 16 wherein the ingot has a cylindrical shape comprising a thickness and a diameter; and wherein any shrinkage cavity formed in a top of the ingot during the casting process has a depth less than 2% of the thickness of the cylindrically-shaped ingot.

19. The method of claim 16 wherein the molten material consists essentially of a metallic material.

20. The method of claim 16 wherein the molten material comprises copper having a purity of at least about 99.995 weight percent.

21. The method of claim 16 wherein the first charge fills from about 50% to about 90% of a volume of the interior cavity.

22. The method of claim 16 wherein the first charge fills from about 5% to about 50% of a volume of the interior cavity.

23. The method of claim 16 wherein the first charge fills about 50% of a volume of the interior cavity; wherein the second charge fills less than or equal to about 10% of the volume of the interior cavity; and further comprising providing additional charges of the molten material within the interior cavity subsequent to the provision of the second charge, each charge being placed within the cavity after only partial solidification of at least some of the material provided in the cavity from preceding charges.

24. A physical vapor deposition target comprising:
a shape, the shape including at least one cup having a first end and a second end in opposing relation to the first end; the first end having an opening extending therein; the cup having a hollow therein; the hollow extending from the opening in the first end toward the second end; the cup having an interior surface defining a periphery of the hollow; the shape including an exterior surface extending around an exterior of the cup and in opposing relation to the interior surface; the exterior surface comprising a region which wraps around at least a portion of the second end with a rounded corner; the rounded corner having a radius of curvature of at least about 1 inch; and
a sputtering surface defined along the interior surface of the cup.

25. The physical vapor deposition target of claim 24 wherein the interior surface does not comprise a rounded corner having a radius of curvature of at least about 1 inch.

26. The physical vapor deposition target of claim 24 wherein the interior surface comprises a rounded corner having a radius of curvature of at least about 1 inch.

27. The physical vapor deposition target of claim 24 wherein the interior surface comprises a rounded corner having a radius of curvature of at least about 1 inch; and wherein the rounded corner of the interior surface is within the rounded corner of the exterior surface.

28. The physical vapor deposition target of claim 24 consisting essentially of high purity copper.

29. The physical vapor deposition target of claim 24 consisting essentially of Ta.

30. The physical vapor deposition target of claim 24 consisting essentially of Ti.

31. The physical vapor deposition target of claim 24 comprising one or more of Cu, Ni, Co, Ta, Al, and Ti.

32. The physical vapor deposition target of claim 24 comprising copper together with one or more of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, and Hf.

33. The physical vapor deposition target of claim 24 consisting essentially of copper and at least one element selected from the group consisting of Cd, Ca, Au, Ag, Be, Li, Mg, Al, Pd, Hg, Ni, In, Zn, B, Ga, Mn, Sn, Ge, W, Cr, O, Sb, Ir, P, As, Co, Te, Fe, S, Ti, Zr, Sc, Sn and Hf; and wherein the copper is present to a concentration of less than or equal to about 99.99%, by weight.

34. The physical vapor deposition target of claim 33 wherein the at least one element is selected from the group consisting of Ag, Al, In, Zn, B, Ga, Mn, Sn, Ge, Ti and Zr.

35. The physical vapor deposition target of claim 33 wherein a total amount of the at least one element is from at least about 100 ppm to less than about 10%, by weight.

36. The physical vapor deposition target of claim 33 wherein a total amount of the at least one element is from at least 1000 ppm to less than about 2%, by weight.

37. The physical vapor deposition target of claim 24 consisting essentially of CuSn, with the Sn being present to from about 100 ppm, by weight, to about 3 atomic percent.

38. The physical vapor deposition target of claim 24 consisting essentially of CuAl, with the Al being present to from about 100 ppm, by weight, to about 3 atomic percent.

39. The physical vapor deposition target of claim 24 consisting essentially of CuAg, with the Ag being present to from about 100 ppm, by weight, to about 3 atomic percent.

40. The physical vapor deposition target of claim 24 wherein the exterior surface wraps entirely around the second end.

41. The physical vapor deposition target of claim 24 wherein the radius of curvature is at least about 1.5 inches.

42. The physical vapor deposition target of claim 24 wherein the radius of curvature is at least about 1.7 inches.

43. The physical vapor deposition target of claim 24 wherein the radius of curvature is at least about 1.8 inches.

44. The physical vapor deposition target of claim 24 wherein the shape consists essentially of a material having an average grain size of less than or equal to 250 microns.

45. The physical vapor deposition target of claim 24 wherein the shape consists essentially of a material having an average grain size of less than or equal to 200 microns.

46. The physical vapor deposition target of claim 24 wherein the shape consists essentially of a material having an average grain size of less than or equal to 100 microns.

47. The physical vapor deposition target of claim 24 wherein the shape consists of a material having an average grain size of less than or equal to 250 microns.

48. The physical vapor deposition target of claim 24 wherein the shape consists of a material having an average grain size of less than or equal to 200 microns.

49. The physical vapor deposition target of claim 24 wherein the shape consists of a material having an average grain size of less than or equal to 100 microns.

50. A magnetron plasma sputter reactor comprising:
a plasma chamber configured to accommodate a substrate to be sputter coated;
the physical vapor deposition target of claim 24 within the chamber; and
a configuration of magnetic materials proximate the target and configured to generate a magnetic field having magnetic field lines extending within the hollow of the target.

51. The magnetron plasma sputter reactor of claim 50 wherein the target interior surface does not comprise a rounded corner having a radius of curvature of at least about 1 inch.

52. The magnetron plasma sputter reactor of claim 50 wherein the target interior surface comprises a rounded corner having a radius of curvature of at least about 1 inch.

53. The magnetron plasma sputter reactor of claim 50 wherein the target interior surface comprises a rounded corner having a radius of curvature of at least about 1 inch; and wherein the rounded corner of the interior surface is within the rounded corner of the exterior surface.

54. The magnetron plasma sputter reactor of claim 50 wherein the target consists essentially of high purity copper.

55. The magnetron plasma sputter reactor of claim 50 wherein the target consists essentially of Ta.

56. The magnetron plasma sputter reactor of claim 50 wherein the target consists essentially of Ti.

57. The magnetron plasma sputter reactor of claim 50 wherein the target comprises one or more of Cu, Ni, Co, Ta, Al, and Ti.

58. The magnetron plasma sputter reactor of claim 50 wherein the target material consists essentially of CuSn, with the Sn being present to from about 100 ppm, by weight, to about 3 atomic percent.

59. The magnetron plasma sputter reactor of claim 50 wherein the target material consists essentially of CuAl, with the Al being present to from about 100 ppm, by weight, to about 3 atomic percent.

60. The magnetron plasma sputter reactor of claim 50 wherein the target material consists essentially of CuAg, with the Ag being present to from about 100 ppm, by weight, to about 3 atomic percent.

61. The magnetron plasma sputter reactor of claim 50 wherein the target exterior surface wraps entirely around the second end.

62. The magnetron plasma sputter reactor of claim 50 wherein the radius of curvature is at least about 1.5 inches.

63. The magnetron plasma sputter reactor of claim 50 wherein the radius of curvature is at least about 1.7 inches.

64. The magnetron plasma sputter reactor of claim 50 wherein the target shape consists essentially of a material having an average grain size of less than or equal to 250 microns.

65. The magnetron plasma sputter reactor of claim 50 wherein the target shape consists essentially of a material having an average grain size of less than or equal to 200 microns.

66. The magnetron plasma sputter reactor of claim 50 wherein the target shape consists essentially of a material having an average grain size of less than or equal to 100 microns.

67. A three-dimensional physical vapor deposition target, comprising:
a material comprising one or more of Cu, Ni, Co, Ta, Al, and Ti;
an average grain size of less than or equal to 250 microns within the material;
a shape, the shape including at least one cup having a first end and a second end in opposing relation to the first end; the first end having an opening extending therein; the cup having a hollow therein; the hollow extending from the opening in the first end toward the second end; the cup having an interior surface defining a periphery of the hollow; and
a sputtering surface defined along the interior surface of the cup.

68. The three-dimensional physical vapor deposition target of claim 67 wherein the material consists essentially of copper; and wherein the target consists essentially of the material.

69. The three-dimensional physical vapor deposition target of claim 67 wherein the material consists essentially of tantalum; and wherein the target consists essentially of the material.

70. The three-dimensional physical vapor deposition target of claim 67 wherein the material consists essentially of CuSn, with the Sn being present to from about 100 ppm, by weight, to about 3 atomic percent; and wherein the target consists essentially of the material.

71. The three-dimensional physical vapor deposition target of claim 67 wherein the material consists essentially of CuAl, with the Al being present to from about 100 ppm, by weight, to about 3 atomic percent; and wherein the target consists essentially of the material.

72. The three-dimensional physical vapor deposition target of claim 67 wherein the material consists essentially of CuAg, with the Ag being present to from about 100 ppm, by weight, to about 3 atomic percent; and wherein the target consists essentially of the material.

73. The three-dimensional physical vapor deposition target of claim 67 wherein the average grain size is less than or equal to 200 microns.

74. The three-dimensional physical vapor deposition target of claim 67 wherein the average grain size is less than or equal to 100 microns.

75. The three-dimensional physical vapor deposition target of claim 67 wherein the average grain size is less than or equal to 90 microns.

76. The three-dimensional vapor deposition target of claim 67 wherein the average grain size is less than or equal to 85 microns.

77. The three-dimensional physical vapor deposition target of claim 67 being in a shape of an Applied Materials Self Ionized Plasma Plus™ target.

78. The three-dimensional physical vapor deposition target of claim 67 being in a shape of a Novellus Hollow Cathode Magnetron™ target.

79. A magnetron plasma sputter reactor comprising:
a plasma chamber configured to accommodate a substrate to be sputter coated;
the three-dimensional physical vapor deposition target of claim 67 within the chamber; and
a configuration of magnetic materials proximate the target and configured to generate a magnetic field having magnetic field lines extending within the hollow of the target.

80. The magnetron plasma sputter reactor of claim 79 wherein the target material consists essentially of copper.

81. The magnetron plasma sputter reactor of claim 79 wherein the target material consists essentially of tantalum.

82. The magnetron plasma sputter reactor of claim 79 wherein the target material consists essentially of CuSn, with the Sn being present to from about 100 ppm, by weight, to about 3 atomic percent.

83. The magnetron plasma sputter reactor of claim 79 wherein the target material consists essentially of CuAl, with the Al being present to from about 100 ppm, by weight, to about 3 atomic percent.

84. The magnetron plasma sputter reactor of claim 79 wherein the target material consists essentially of CuAg, with the Ag being present to from about 100 ppm, by weight, to about 3 atomic percent.

85. The magnetron plasma sputter reactor of claim 79 wherein the target material average grain size is less than or equal to 200 microns.

86. The magnetron plasma sputter reactor of claim 79 wherein the target material average grain size is less than or equal to 100 microns.

87. The magnetron plasma sputter reactor of claim 79 wherein the target material average grain size is less than or equal to 90 microns.

88. The magnetron plasma sputter reactor of claim 79 wherein the target material average grain size is less than or equal to 85 microns.

89. The magnetron plasma sputter reactor of claim 79 wherein the target shape is that of an Applied Materials Self Ionized Plasma Plus™ target.
